(19) United States
(12) Patent Application Publication
(10) Pub. No.: US 2017/0084448 A1
(43) Pub. Date: Mar. 23, 2017

(54) LOW TEMPERATURE CONFORMAL DEPOSITION OF SILICON NITRIDE ON HIGH ASPECT RATIO STRUCTURES

(71) Applicant: Applied Materials, Inc., Santa Clara, CA (US)

(72) Inventors: Soumendra Narayan BARMAN, San Jose, CA (US); Jian J. CHEN, Fremont, CA (US); Praket P. JHA, San Jose, CA (US); Bok Hoen KIM, San Jose, CA (US); Miguel S. FUNG, Sunnyvale, CA (US)

(21) Appl. No.: 15/263,869

(22) Filed: Sep. 13, 2016

Related U.S. Application Data
(60) Provisional application No. 62/220,422, filed on Sep. 18, 2015.

(51) Int. Cl. H01L 21/02; C23C 16/452; C23C 16/34; C23C 16/505

(52) U.S. Cl. CPC H01L 21/0217; H01L 21/02205; H01L 21/02274; C23C 16/505; C23C 16/452; C23C 16/345

(57) ABSTRACT

Embodiments described herein generally relate to methods for forming a conformal silicon nitride layer at low temperatures. The conformal silicon nitride layer may be formed by pulsing a radio frequency (RF) power into a processing chamber while a gas mixture including trisilylamine is flowing into the processing chamber. Pulsed RF power increases the ratio of neutral to ionic species and activated species of trisilylamine have low sticking coefficients and greater surface migration. As a result, conformality of the deposited silicon nitride layer is improved.

### CROSS-REFERENCE TO RELATED APPLICATIONS

This application claims priority to U.S. Provisional Patent Application Ser. No. 62/220,422, filed on Sep. 18, 2015, which herein is incorporated by reference.

### BACKGROUND

Field

Embodiments described herein generally relate to methods for forming a conformal silicon nitride layer at low temperatures.

Description of the Related Art

The electronic device industry and the semiconductor industry continue to strive for larger production yields while increasing the uniformity of layers deposited on substrates having increasingly larger surface areas. These same factors in combination with new materials also provide higher integration of circuits per unit area on the substrate. As circuit integration increases, the need for greater uniformity and process control regarding layer characteristics rises.

Conformal coverage, with low pattern loading effect, of dielectric layers on high aspect ratio structures and/or three dimensional (3D) structures are of critical requirement as device node shrinks down to below 22 nm, and as the manufacture of 3D transistors increases. Silicon nitride layers may be used throughout integrated circuit formation, such as gate spacers, liner layers, sacrificial layers, barrier layers, etc. Silicon nitride layers formed using thermal processes offers good conformality. The drawbacks, however, include a high temperature requirement (typically greater than 400° C.) and few capabilities to engineer film compositions and properties for different applications. Alternatively, conventional plasma enhanced chemical vapor deposition (PECVD) silicon nitride layers have poorer step coverage due to directionality of radicals' fluxes.

Therefore, there is a need for a low temperature process to form a conformal silicon nitride layer.

### SUMMARY

Embodiments described herein generally relate to methods for forming a conformal silicon nitride layer at low temperatures. The conformal silicon nitride layer may be formed by pulsing a radio frequency (RF) power into a processing chamber while a gas mixture including trisilylamine is flowing into the processing chamber. Pulsed RF power increases the ratio of neutral to ionic species and activated species of trisilylamine have low sticking coefficients and greater surface migration. As a result, conformality of the deposited silicon nitride layer is improved.

In one embodiment, a method for forming a silicon nitride layer includes flowing trisilylamine into a processing chamber, and activating the trisilylamine by forming a plasma while the trisilylamine is flowing into the processing chamber. The plasma is formed by pulsing RF power. The method further includes forming the silicon nitride layer on a substrate disposed in the processing chamber.

In another embodiment, a method for forming a silicon nitride layer includes flowing a gas mixture into a processing chamber. The gas mixture includes trisilylamine and a different nitrogen-containing precursor. The method further includes activating the gas mixture by forming a plasma while the trisilylamine is flowing into the processing chamber. The plasma is formed by pulsing RF power. The method further includes forming the silicon nitride layer on a substrate disposed in the processing chamber.

In another embodiment, a method for forming a silicon nitride layer includes flowing a gas mixture into a processing chamber. The gas mixture includes trisilylamine and a second nitrogen-containing precursor. The method further includes forming activated species of the trisilylamine and the second nitrogen-containing precursor by pulsing RF power into the processing chamber while the trisilylamine is flowing into the processing chamber. The method further includes reacting the activated species of the trisilylamine and the second nitrogen-containing precursor to form a reaction product on a substrate disposed in the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic sectional view of a plasma processing chamber according to embodiments described herein.

FIG. 2 illustrates a method for forming a conformal silicon nitride layer according to embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to methods for forming a conformal silicon nitride layer at low temperatures. The conformal silicon nitride layer may be formed by pulsing a radio frequency (RF) power into a processing chamber while a gas mixture including trisilylamine is flowing into the processing chamber. Pulsed RF power increases the ratio of neutral to ionic species and activated species of trisilylamine have low sticking coefficients and greater surface migration. As a result, conformality of the deposited silicon nitride layer is improved.

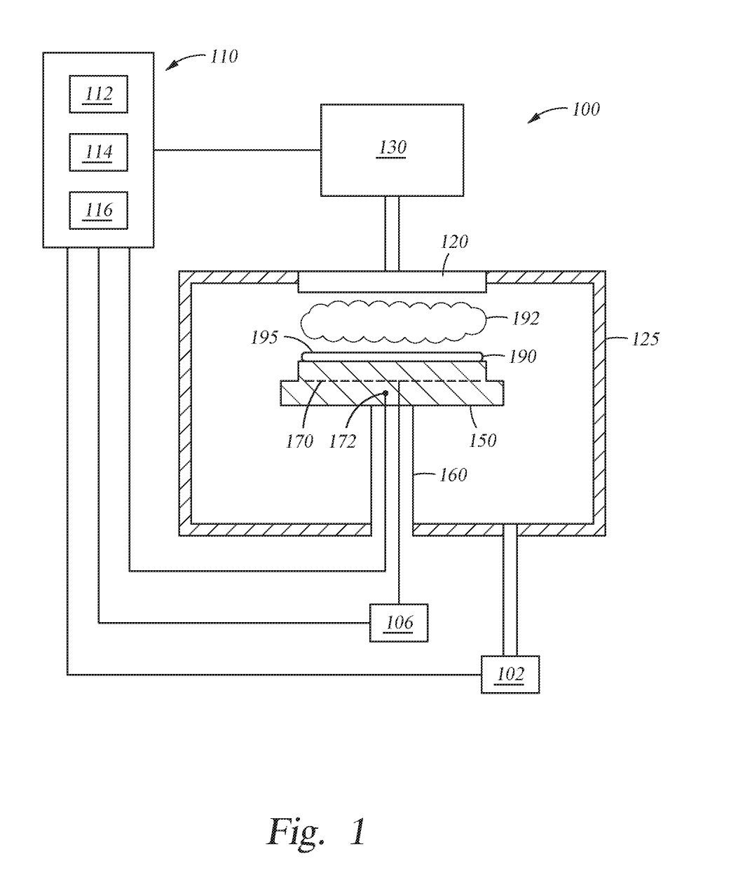

FIG. 1 is a schematic representation of a substrate processing system 100, which can be used for low temperature conformal silicon nitride layer deposition according to embodiments described herein. Examples of suitable systems include the CENTURA® systems which may use a DxZ™ processing chamber, PRECISION 5000® systems, PRODUCER™ systems, such as the PRODUCER™ processing chamber and the PRODUCER GT™ processing chamber, all of which are commercially available from Applied Materials, Inc., Santa Clara, Calif.

System 100 includes a processing chamber 125, a gas panel 130, a control unit 110, and other hardware components such as power supplies and vacuum pumps. The processing chamber 125 generally comprises a substrate support pedestal 150, which is used to support a substrate such as a semiconductor substrate 190. The substrate support pedestal 150 may move in a vertical direction inside the processing chamber 125 using a displacement mechanism (not shown) coupled to a shaft 160. Depending on the process, the semiconductor substrate 190 can be heated to a predetermined temperature prior to processing. The substrate support pedestal 150 may be heated by an embedded heater element 170. For example, the substrate support pedestal 150 may be resistively heated by applying an electric current from a power supply 106 to the heater element 170. The semiconductor substrate 190 is, in turn, heated by the substrate support pedestal 150. A temperature sensor 172, such as a thermocouple, may be also embedded in the substrate support pedestal 150 to monitor the temperature of the substrate support pedestal 150. The measured temperature is used in a feedback loop to control the power supply 106 for the heater element 170. The substrate temperature can be maintained or controlled at a temperature that is selected for the particular process application.

A vacuum pump 102 is used to evacuate the processing chamber 125 and to maintain the proper gas flows and pressure inside the processing chamber 125. A showerhead 120, through which a gas mixture of process gases are introduced into the process chamber 125, is located above the substrate support pedestal 150 and is adapted to provide a uniform distribution of the gas mixture into the processing chamber 125. The showerhead 120 may be connected to the gas panel 130, which controls and supplies various process gases used in different steps of the process sequence. Process gases may be flowed into the gas panel 130 at different flow rates. In some embodiments, process gases may be individually and simultaneously flowed into the processing chamber, and the flow rates of the process gases may be different. Process gases of the gas mixture may include trisilylamine (TSA) and a nitrogen-containing precursor gas other than TSA and are described in more detail below in conjunction with a description of an exemplary deposition process. Process gases may be vaporized liquid precursors. While not shown, liquid precursors from a liquid precursor supply may be vaporized, for example, by a liquid injection vaporizer, and delivered to the processing chamber 125 in the presence of a carrier gas. The carrier gas is typically an inert gas, such as argon or helium. Alternatively, the liquid precursor may be vaporized from an ampoule by a thermal and/or vacuum enhanced vaporization process.

The showerhead 120 and substrate support pedestal 150 may also form a pair of spaced electrodes. When an electric field is generated between these electrodes, the gas mixture introduced into chamber 125 is ignited into a plasma 192. Typically, the electric field is generated by connecting the substrate support pedestal 150 to a source of single-frequency or dual-frequency RF power (not shown) through a matching network (not shown). Alternatively, the RF power source and matching network may be coupled to the showerhead 120, or coupled to both the showerhead 120 and the substrate support pedestal 150. The RF power may be pulsed in order to improve conformality of the silicon nitride layer deposited on the substrate 190.

PECVD techniques promote excitation and/or disassociation of the process gases by the application of the electric field to the reaction zone near the substrate surface, creating a plasma of reactive species.

Proper control and regulation of the gas flows through the gas panel 130 is performed by mass flow controllers (not shown) and a control unit 110 such as a computer. The showerhead 120 allows process gases from the gas panel 130 to be uniformly distributed and introduced into the processing chamber 125. Illustratively, the control unit 110 comprises a central processing unit (CPU) 112, support circuitry 114, and memories containing associated control software 116. This control unit 110 is responsible for automated control of the numerous steps for substrate processing, such as substrate transport, gas flow control, liquid flow control, temperature control, chamber evacuation, and so on. When the gas mixture exits the showerhead 120, plasma enhanced activation of the process gases occurs, resulting in forming a reaction product between the activated species. The reaction product is then deposited on the surface 195 of semiconductor substrate 190. The surface 195 of the substrate 190 may include a plurality of trenches having a high aspect ratio, such as 5:1 to 12:1, and the reaction product deposited in the trenches may be a conformal silicon nitride layer. The conformal nature is defined by the conformality of the film. Conformality is referring to the ratio of the thickness of the silicon nitride layer at the top side wall of the trench to the thickness of the silicon nitride layer at the bottom of the trench.

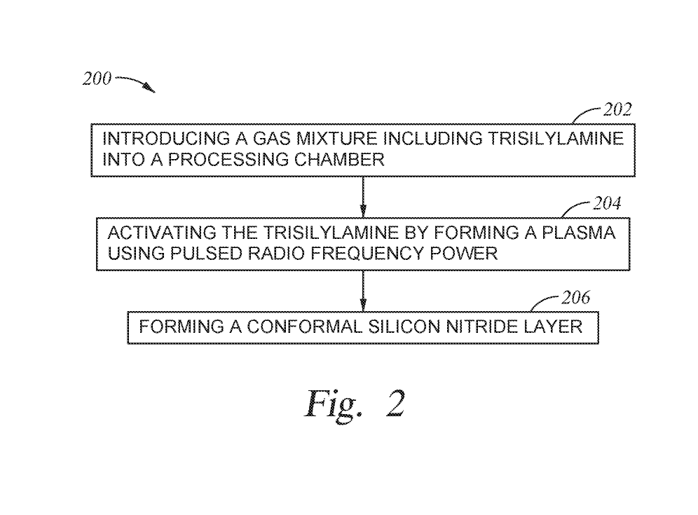

FIG. 2 illustrates a method 200 for forming a conformal silicon nitride layer according to embodiments described herein. First, at block 202, a gas mixture is introduced into a processing chamber. The gas mixture may include process gases including TSA and a second nitrogen-containing precursor, such as nitrogen gas, ammonia, or hydrazine. In some embodiments, silane or disilane may be used instead of TSA. The gas mixture may also include a carrier gas, such as argon. The processing chamber may be the processing chamber 125 described in FIG. 1. A substrate, such as the substrate 190 shown in FIG. 1, may be disposed in the processing chamber. The substrate may be heated to a temperature less than 300 degrees Celsius, such as about 280 degrees Celsius. The flow rate of the TSA may be slower than the flow rates of the second nitrogen-containing precursor and the carrier gas, leading to the gas mixture having a low concentration of TSA. Having low concentration of TSA helps decrease deposition rate while increases conformality. Low concentration of TSA reduces the gas phase recombination of the reactive species resulting in smaller adsorbed molecules on the surface. These smaller adsorbed molecules can have a lower sticking coefficient and a greater surface mobility.

Next, at block 204, the process gases of the gas mixture are activated by forming a plasma in the processing chamber. Activation of the process gases means forming reactive species, such as radicals and ions, from the less reactive process gases before the process gases reach the substrate. Activation of the process gases can be done by forming a plasma in the processing chamber with pulsed RF power. Plasma formed with pulsed RF power increases the ratio of neutral to ion species resulting from the RF plasma. The increase in long lived neutral species allows for diffusion into nanometer sized features, avoids electron shading effects, and increases migration of adsorbed species on the surface resulting in improved conformality. Activated species of TSA have lower sticking coefficients and greater surface migration. In addition, the pressure of the processing chamber may be low in order to decreases gaseous molecular interactions or recombination. The pressure may range from about 1 mtorr to about 15 mtorr.

The RF power may be pulsed and may have a frequency ranging from about 1 Hz to over 100,000 Hz and a relatively low power, such as about 25 W to about 300 W. In one embodiment, the RF power is about 100 W and has a frequency of about 1,000 Hz. The RF power may be pulsed for a period of time while the gas mixture is flowing into the processing chamber, based on the predetermined thickness of the silicon nitride layer. The time period may range from about 5 seconds to greater than 300 seconds, such as from about from 15 seconds to about 90 seconds. The duty cycle of the pulsed RF power may range from about 5 percent to about 95 percent, such as about 5 percent to about 30 percent.

Next, at block 206, the conformal silicon nitride layer is formed on the substrate. The silicon nitride layer may be conformally formed in the trenches with high aspect ratio. The conformal silicon nitride layer may be the reaction product of the activated species. The activated species may be first deposited on the surface of the substrate and then reacted to form the conformal silicon nitride layer. Alternatively or in addition to, the activated species may be reacted prior to reaching the surface of the substrate, and the reaction product is deposited on the surface of the substrate.

By forming a silicon nitride layer using pulsed RF power and TSA as a precursor at a low temperature, such as less than 300 degrees Celsius, the conformality of the silicon nitride layer is improved. In addition, the layer quality, such as leakage, etch rate, and density, is also improved.

While the foregoing is directed to embodiments of the present disclosure, other and further embodiments of the disclosure may be devised without departing from the basic scope thereof, and the scope thereof is determined by the claims that follow.

1. A method for forming a silicon nitride layer, comprising:
flowing trisilylamine into a processing chamber;
activating the trisilylamine by forming a plasma while the trisilylamine is flowing into the processing chamber, wherein the plasma is formed by pulsing radio frequency power; and
forming the silicon nitride layer on a substrate disposed in the processing chamber.

2. The method of claim 1, further comprising simultaneously flowing a second nitrogen-containing precursor into the processing chamber while flowing the trisilylamine into the processing chamber.

3. The method of claim 2, wherein the second nitrogen-containing precursor is nitrogen gas, ammonia, or hydrazine.

4. The method of claim 2, wherein the flowing of the trisilylamine into the processing chamber has a first flow rate and the flowing of the second nitrogen-containing precursor into the processing chamber has a second flow rate, wherein the second flow rate is greater than the first flow rate.

5. The method of claim 2, further comprising flowing a carrier gas into the processing chamber, wherein the second nitrogen-containing precursor, the trisilylamine, and the carrier gas are flowing into the processing chamber simultaneously.

6. The method of claim 5, wherein the carrier gas comprises argon gas or helium gas.

7. The method of claim 1, wherein the radio frequency power has a frequency that ranges from about 1 Hz to about 100,000 Hz.

8. The method of claim 1, wherein the radio frequency power has a frequency that is about 1,000 Hz.

9. A method for forming a silicon nitride layer, comprising:
flowing a gas mixture into a processing chamber, wherein the gas mixture comprises trisilylamine and a different nitrogen-containing precursor;
activating the gas mixture by forming a plasma while the trisilylamine is flowing into the processing chamber, wherein the plasma is formed by pulsing radio frequency power; and
forming the silicon nitride layer on a substrate disposed in the processing chamber.

10. The method of claim 9, wherein the different nitrogen-containing precursor is nitrogen gas, ammonia, or hydrazine.

11. The method of claim 9, wherein the gas mixture further comprises a carrier gas.

12. The method of claim 11, wherein the carrier gas comprises argon gas or helium gas.

13. The method of claim 9, wherein the radio frequency power has a frequency that ranges from about 1 Hz to about 100,000 Hz.

14. The method of claim 9, wherein the radio frequency power has a frequency that is about 1,000 Hz.

15. The method of claim 9, wherein the radio frequency power has a power that is about 100 W.

16. A method for forming a silicon nitride layer, comprising:
flowing a gas mixture into a processing chamber, wherein the gas mixture comprises trisilylamine and a second nitrogen-containing precursor;
forming activated species of the trisilylamine and the second nitrogen-containing precursor by pulsing radio frequency power into the processing chamber while the trisilylamine is flowing into the processing chamber; and
reacting the activated species of the trisilylamine and the second nitrogen-containing precursor to form a reaction product on a substrate disposed in the processing chamber.

17. The method of claim 16, wherein the second nitrogen-containing precursor comprises nitrogen gas, ammonia, or hydrazine.

18. The method of claim 16, wherein the radio frequency power has a frequency that ranges from about 1 Hz to about 100,000 Hz.

19. The method of claim 16, wherein the radio frequency power has a frequency that is about 1,000 Hz.

20. The method of claim 16, wherein the reaction product is silicon nitride.
